(19) United States
(12) Patent Application Publication
(10) Pub. No.: US 2011/0018434 A1
(43) Pub. Date: Jan. 27, 2011

(54) ORGANIC ELECTROLUMINESCENCE (EL) ELEMENT AND MANUFACTURING METHOD THEREOF

(76) Inventor: Satoshi Miyaguchi, Saitama (JP)

Correspondence Address: WENDEROTH, LIND & PONACK, L.L.P., 1030 15th Street, N.W.,, Suite 400 East, Washington, DC, 20005-1503, US

(21) Appl. No.: 12/450,287

(22) PCT Filed: Mar. 22, 2007
(86) PCT No.: PCT/JP2007/055842

§ 371 Date: Sep. 18, 2009

(51) Int. Cl. H05B 33/12; B05D 5/06; B05D 5/12

(52) U.S. Cl. 313/512; 427/66

(57) ABSTRACT

[Problems] To provide an organic EL element capable of preventing an electrical short circuit even when a leakage current occurs and a manufacturing method thereof.

[Solving Means] The organic EL element has an arrangement in which an inorganic seal film (7) seals a stacked structure including a first electrode (3), an organic EL layer (4), a second electrode (5), and a low-temperature sublimation layer (6) stacked in order over a substrate (2). The layer (6) is formed of amaterial which sublimes at a temperature lower than the melting point of the second electrode. With such an arrangement, when a leakage current occurs to generate heat locally in the second electrode, the low-temperature sublimation layer (6) sublimes to form a void into which the second electrode (5) extends to be an opened state. As a result, an electric short circuit can be prevented.

### TECHNICAL FIELD

The present invention relates to an organic electroluminescence (EL) element and a manufacturing method thereof.

### BACKGROUND ART

Organic EL elements are a type of self-emission element based on an electroluminescence phenomenon of organic substances and are an important device used to provide displays, lighting and the like in electronic products. The organic EL element has advantages such as higher image quality, a wider viewing angle, and driving with lower power over conventional liquid crystal elements, and can be manufactured at a low cost. Thus, the organic EL element is expected as an important element for realizing displays better than liquid crystal displays and plasma displays.

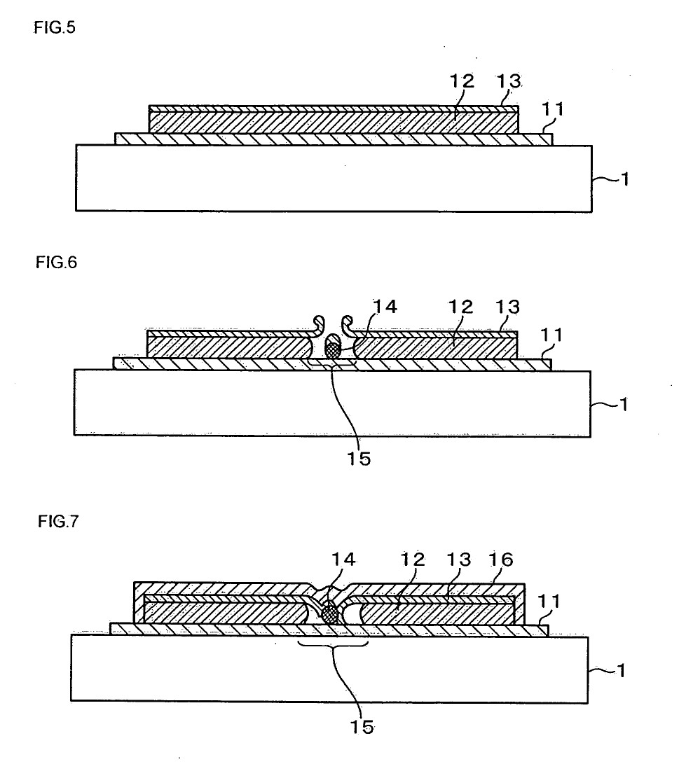

As shown in FIG. 5, an organic EL element is formed such that an anode 11 made of a metal oxide thin film of ITO (Indium Tin Oxide) or the like, an organic EL layer 12, and a cathode 13 made of a metal thin film of Al or the like are stacked in order over an upper surface of a transparent substrate 1. The organic EL layer 12 is formed to have stacked organic thin films including a hole injection layer, a hole transport layer, a light-emitting layer, and an electronic injection layer. When holes and electrons are injected through the anode 11 and the cathode 13, the organic EL layer 12 emits light by excitons produced in recombination of the electrons and holes within the light-emitting layer.

While the organic EL element has the abovementioned advantages, it has two problems described below. The first one of the problems is that the organic EL element is extremely susceptible to outgas such as water vapor and oxygen and thus the cathode 13 is deteriorated from oxidation or peeled to expand readily an irreversible non-light-emitting area such as a so-called dark spot (black spot). To address this, a proposal has been made of a structure which is sealed with a hollow lid having a water catch component attached to the interior for absorbing water vapor or the like (for example, see Patent Document 1). With such a structure, the water catch component absorbs outgas from the substrate or the element, water vapor entering from the outside and the like to prevent expansion of the non-light-emitting area.

The hollow lid as in Patent Document 1, however, increases the thickness of the element to limit the realization of thinner elements which have been increasingly needed in recent years. For this reason, another proposal has been made of a technique in which entry of water vapor or oxygen is prevented by forming an inorganic seal film (inorganic barrier film) in intimate contact, for example made of silicon nitride (SiNₓ) having a low permeability of water vapor and oxygen (for example, see Patent Document 2).

The second one of the problems is that the organic EL element includes the extremely thin organic EL layer 12 having a submicron thickness sandwiched between the anode 11 and the cathode 13, and thus minute irregularities present between the electrodes due to flaws of the anode 11 or foreign matters such as minute dust may reduce the distance between the electrodes to produce a leakage current readily. To solve the problem, as schematically shown in FIG. 6, a proposal has been made of a technique in which a reverse bias voltage is applied to an element to inject an electric current concentratedly into a spot (leak spot 15) where the distance between electrodes is reduced due to a foreign matter 14 or the like, so that the cathode 13 is heated by the action of Joule heat and melted to extend in a direction opposite to the anode 11 (for example, see Patent Document 3). The cathode 13 positioned at the leak spot 15 is extended in the direction away from the anode 11 in this manner (this state is referred to as “an opened state”) to suppress the leakage current and to prevent contact between the cathode 13 and the anode 11 to avoid occurrence of a secondary electrical short circuit.

When the electrode is in the opened state as shown in FIG. 6, that spot becomes as a non-light-emitting area. However, the area actually has a small size which cannot be visually recognized, and the remaining light-emitting area can sufficiently maintain the light-emitting function of the element. In contrast, if the cathode 13 extends downward and contacts the anode 11 to cause an electrical short circuit, the element cannot operate normally thereafter. Thus, the prevention of occurrence of an electrical short circuit is significantly effective.

On the other hand, if the opened state of the cathode 13 permits entry of water vapor or oxygen, the abovementioned first problem becomes more serious. A possible countermeasure is to cover the element with a hollow lid as in Patent Document 1. In this case, however, the realization of thinner elements is limited. As schematically shown in FIG. 7, when an inorganic seal film 16 as in Patent Document 2 is formed in intimate contact with an upper surface of the cathode 13, the cathode 13 is obstructed by the inorganic seal film 16 and cannot extend upward but may be bent toward the anode 11 to cause an electrical short circuit. In addition, even when the cathode 13 can push up the inorganic seal film 16 to extend upward, it is feared that the inorganic seal film 16 may suffer a defect such as a crack and peeling to allow entry of water vapor and oxygen therethrough.

Patent Document 4 has disclosed a structure which has at least two stacked films consisting of a buffer layer (buffering layer) and a barrier layer (seal layer) placed thereon. The buffer layer in Patent Document 4, however, is provided for the purpose of covering and planarizing a defective element to prevent expansion of a dark spot. No consideration is given to prevention of occurrence of a leakage due to a defect.

[Patent Document 1] Japanese Patent Laid-Open No. 09 (1997)-148066

[Patent Document 2] Japanese Patent Laid-Open No. 2000-77183

[Patent Document 3] Japanese Patent Laid-Open No. 11-305727

[Patent Document 4] Japanese Patent Laid-Open No. 10 (1998)-312883

### DISCLOSURE OF THE INVENTION

### Problems to be Solved by the Invention

Problems to be solved by the present invention include the abovementioned ones. It is thus an object of the present invention to provide an organic EL element having a structure including an inorganic seal film formed in intimate contact in order to reduce the thickness of the element, in which an electrical short circuit can be prevented even when a leakage current occurs, and a manufacturing method thereof, by way of example.

It is another object of the present invention to provide an organic EL element in which a defect can be prevented in an inorganic seal film when an electrode placed on an upper side is in opened state, and a manufacturing method thereof, by way of example.

### Means for Solving the Problems

As described in claim 1, the present invention provides an organic EL element in which a first electrode, an organic EL layer, a second electrode, a low-temperature sublimation layer, and an inorganic seal film are stacked in order over a substrate, wherein the low-temperature sublimation layer is formed of a material which sublimes at a temperature lower than the melting point of the second electrode.

As described in claim 8, the present invention provides a method of manufacturing an organic EL element in which a first electrode, an organic EL layer, a second electrode, a low-temperature sublimation layer, and an inorganic seal film are stacked in order over a substrate, including a step of carrying the substrate having the first electrode formed thereon into an evaporation apparatus to form in order the organic EL layer, the second electrode, and the low-temperature sublimation layer made of a material which sublimes at a temperature lower than the melting point of the second electrode, and a step of carrying the substrate having the low-temperature sublimation layer formed thereover into an inorganic-seal-film deposition apparatus such as a plasma CVD apparatus without exposure to the atmosphere to form the inorganic seal film.

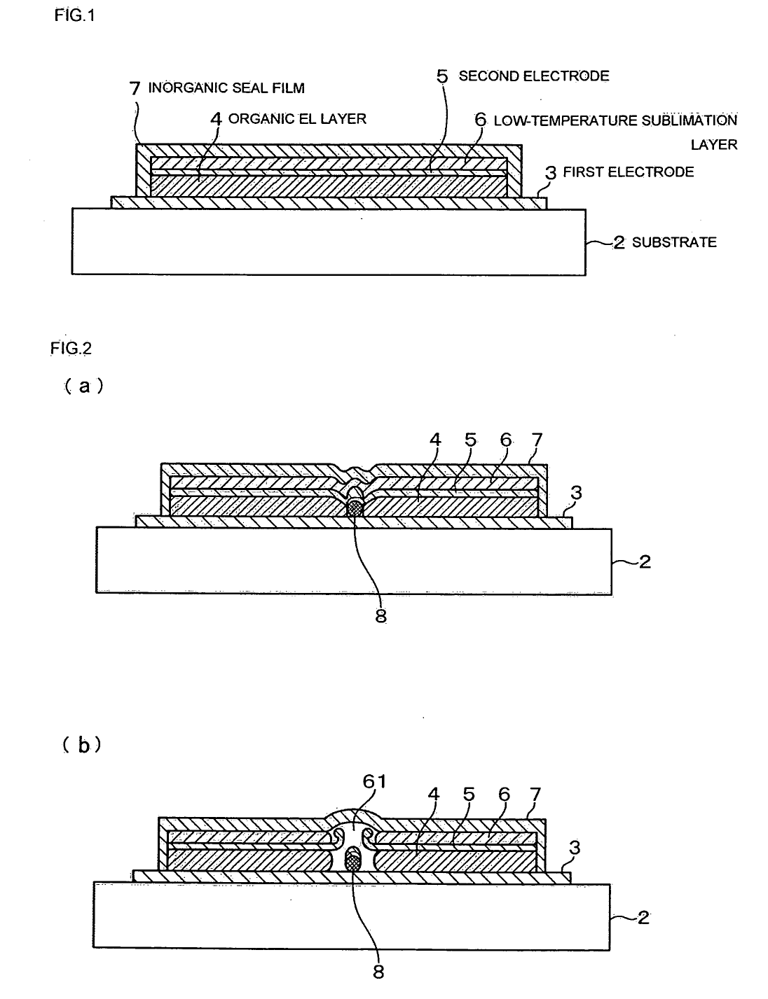

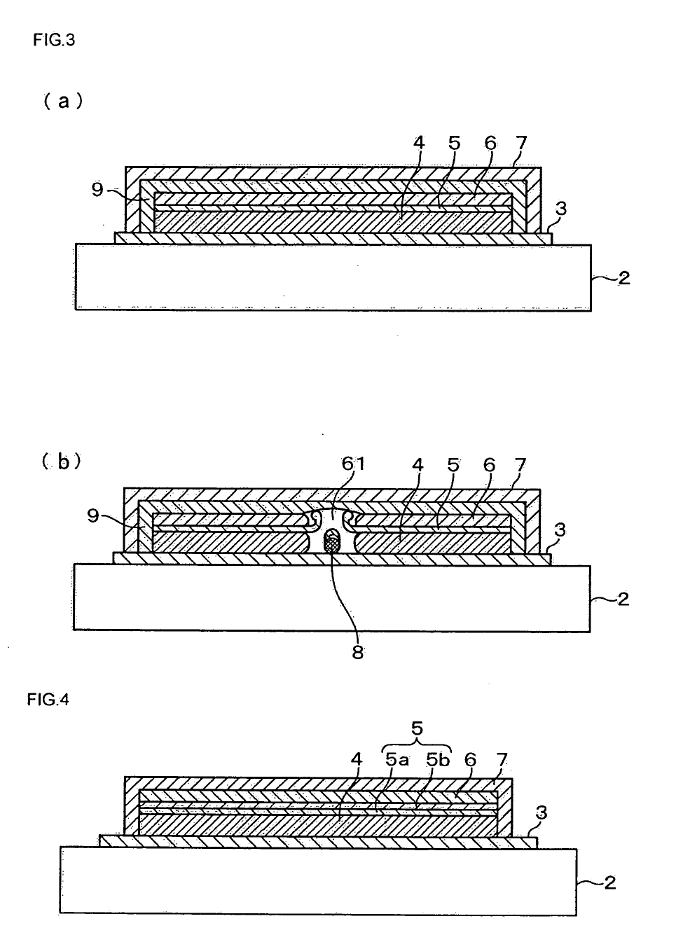

### BRIEF DESCRIPTION OF DRAWINGS

[FIG. 1] A longitudinal section view schematically showing an organic EL element according to Embodiment 1 of the present invention.

[FIG. 2] A diagram schematically showing an electrode in an opened state of the organic EL element shown in FIG. 1.

[FIG. 3] A longitudinal section view schematically showing an organic EL element according to Embodiment 2 of the present invention.

[FIG. 4] A longitudinal section view schematically showing an organic EL element according to Embodiment 4 of the present invention.

[FIG. 5] A section view schematically showing an organic EL element in the related art.

[FIG. 6] A diagram schematically showing an electrode in an opened state of the organic EL element shown in FIG. 5.

[FIG. 7] A diagram schematically showing an electrical short circuit of the organic EL element in the related art.

### DESCRIPTION OF REFERENCE NUMERALS

2 SUBSTRATE
3 FIRST ELECTRODE
4 ORGANIC EL LAYER
5 SECOND ELECTRODE
5a FIRST CONDUCTIVE THIN FILM
5b SECOND CONDUCTIVE THIN FILM
6 LOW-TEMPERATURE SUBLIMATION LAYER
61 VOID
7 INORGANIC SEAL FILM
8 FOREIGN MATTER
9 BUFFERING LAYER

### BEST MODE FOR CARRYING OUT THE INVENTION

An organic EL element according to preferred embodiments of the present invention will be described in detail with reference to the accompanying drawings. However, the present invention is not limited to the embodiments described below.

### Embodiment 1

As shown in FIG. 1, an organic EL element according to Embodiment 1 includes a first electrode 3, an organic EL layer 4, a second electrode 5, and a low-temperature sublimation layer 6 made of a material subliming at a temperature lower than the melting point of the second electrode 5, all of which are stacked in order over a transparent substrate 2. An inorganic seal film (inorganic barrier layer) 7 is also formed to cover an upper surface of the low-temperature sublimation layer 6 and a side portion ranging from the low-temperature sublimation layer 6 to the organic EL layer 4. One of the first electrode 3 and the second electrode 5 is formed as an anode and the other is formed as a cathode. Which one is formed as the anode out of the first electrode 3 and the second electrode 5 may be determined on the depending on the use of the element and the like. In the following, description will be made with an example in which the first electrode 3 is formed as the anode.

The substrate 2 may be provided by using a substrate of flat plate shape or film shape based on the use of the element, for example. Materials thereof may be selected as appropriate based on the use of the element, and for example, a glass substrate or a plastic substrate may be selected. When the organic EL element is of a bottom emission type in which the light emitted by the organic EL layer 4 is output through the substrate 2, a transparent material is used for the substrate 2.

The anode 3 is formed by using a material having a high work function in a thin film shape having a thickness of 10 nm to 500 nm, for example. Examples of the materials of the anode 3 include, for example, a metal oxide such as ITO (Indium Tin Oxide) and IZO (Indium Zinc Oxide). The materials are not limited thereto, and it is possible to use a metal such as Cr, Mo, Ni, Pt, Au, and Ag or a compound thereof or an alloy containing any of them. For an organic EL element of the bottom emission type in which the light emitted by the organic EL layer 4 is output through the substrate, a light-transmitting material is used such as ITO and IZO, or a material having a high reflectivity such as a metal is deposited to be so thin as to transmit light therethrough. Although omitted in FIG. 1, an extraction electrode (wiring electrode) is connected to the anode 3.

The cathode 5 is formed by using a material having a low work function in a thin film shape having a thickness of 2 nm to 1000 nm, for example. Examples of the materials of the cathode 5 include a metal such as aluminum (Al) (melting point: 660.1° C.), Mg (melting point: 650° C.),

Ag (melting point: 960.8° C.), Au (melting point: 1063° C.), Ca (melting point: 845° C.), and Li (melting point: 180.5° C.), a compound thereof, or an alloy containing any of them. Of them, aluminum is preferable since it can provide favorable characteristics for the organic EL element. Although omitted in FIG. 1, an extraction electrode (wiring electrode) is connected to the cathode 5.

The organic EL layer 4 is an organic thin film formed in a thin film shape having a thickness of 50 nm to 1000 nm, for example. It is essential only that the organic EL layer 4 should include at least a light-emitting layer, but the layer 4 preferably has a stacked structure including a hole injection layer, a hole transport layer, a light-emitting layer, and an electron injection layer stacked in order from the anode side to promote an electroluminescence phenomenon. However, the layer 4 is not limited thereto and may further include an electron transport layer, a hole barrier layer, an electron barrier layer and the like.

The hole injection layer and the hole transport layer may be formed of a material having excellent hole transport properties. Examples of usable organic materials include a phthalocyanine compound such as copper phthalocyanine (CuPc), starburst type amine such as m-MTDATA, a multimer of benzidine type amine, aromatic tertiary amine such as 4,4′-bis[N-(1-naphtyl)-N-phenylamino]-biphenyl (NPB), N-phenyl-p-phenylenediamine (PPD), a stilbene compound such as 4-(di-P-tolylamino)-4′-[4-(di-P-tolylamino)styryl]stylbenzene, a triazole derivative, a styrylamine compound, and a fullerene such as buckyball and C₆₀. It is also possible to use a material of a polymer dispersed type provided by dispersing a low-molecular material in a high-molecular material such as polycarbonate. However, the materials are not limited thereto.

It is essential only that the organic light-emitting layer should have the function of producing the electroluminescence phenomenon. Example of usable materials include a fluorescent organic metal compound such as tris(8-hydroxyquinolinate) aluminum complex (Alq₃), a aromatic dimethylidine compound such as 4,4′-bis(2,2′-diphenylvinyl)-biphenyl (DPVBi), a styrylbenzene compound such as 1,4-bis(2-methylstyryl)benzene, a triazole derivative such as 3-(4-biphenyl)-4-phenyl-5-t-butylphenyl-1,2,4-triazole (TAZ), a anthraquinone derivative, a fluorescent organic material such as a fluorenone derivative, a polymer material of polyparaphenylene vinylene (PPV) base, polyfluorene base, and polyvinylcarbazole (PVK) base, and a phosphorescent organic material such as a platinum complex and an iridium complex. However, the materials are not limited thereto.

The electron injection layer and the electron transport layer maybe formed of a material having excellent electron transport properties. Examples of the usable material include a metal oxide such as lithium oxide (Li₂O), an organic material such as a silacyclopentadiene (silole) derivative including PyPySPyPy, a nitro-substituted fluorenone derivative, and an anthraquinodimethane derivative, a metal complex of a 8-quinolinole derivative such as tris(8-hydroxyquinolinate)aluminum (Alq₃), metal phthalocyanine, a triazole-based compound such as 3-(4-biphenyl)-5-(4-t-butylphenyl)-4-phenyl-1,2,4-triazole (TAZ), an oxadiazole-based compound such as 2-(4-biphenylyl)-5-(4-t-butyl)-1,3,4-oxadiazole (PBD), and a fullerene such as buckyball, C₆₀, and carbon nanotube.

The low-temperature sublimation layer 6 is formed of a material subliming at a temperature lower than the melting point of the second electrode 5. When the second electrode locally generates heat due to a leakage current, the portion of the low-temperature sublimation layer 6 adjacent thereto sublimes to form a void for allowing upward extension of the second electrode 5. The type of the material forming the low-temperature sublimation layer 6 may be determined as appropriate in view of the type of the material forming the second electrode 5. Copper phthalocyanine (CuPc) which sublimes at a relatively low temperature (sublimation temperature: approximately 460° C.) is preferably used. CuPc is one of the possible materials forming the organic EL layer 4 as described above. Such selection of the same material as that of the organic EL layer 4 has the advantages that the material cost can be reduced and the manufacturing process can be simplified. However, the material is not limited to CuPc, and any sublimable organic material may be used that sublimes at a temperature lower than the melting point of the second electrode 5. In addition, the material is not limited to organic materials, and an inorganic material or an organic-inorganic hybrid material maybe used that satisfies the abovementioned requirement. The low-temperature sublimation layer 6 may not be a single layer film made of the abovementioned material but may be a stacked film made of a combination of a plurality of materials.

The material which sublimes at a temperature lower than the melting point of the second electrode 5 refers to any material which changes in phase from solid to gas by skipping liquid but do not include any material which changes in phase from solid to gas through liquid at a temperature lower than the melting point of the second electrode 5. This is because, once the low-temperature sublimation layer 6 is liquefied, the liquefaction proceeds in this state or the layer 6 flows in the film surface direction to change the film thickness of the low-temperature sublimation layer, and even when the temperature rises to vaporize the material of the low-temperature sublimation film, the initially expected results cannot be provided. If the second electrode 5 is formed of a stack of a plurality of conductive thin films, one of the conductive thin films that has the lowest melting point is taken into consideration. It is preferable to use a material which sublimes at a temperature lower than the melting point of that conductive thin film.

The low-temperature sublimation layer 6 may be deposited to have a thickness of 100 nm to 10000 nm, for example. The layer 6 is preferably formed to have a film thickness larger than the length of an upward bent part of the second electrode when it is in an opened state:

The inorganic seal film 7 may be formed of a material having a low permeability of water vapor and oxygen. Examples of the material include silicon nitride (SiNₓ), silicon oxynitride (SiOxNy), aluminum oxide (AlOx), and aluminum nitride (AlNx). Examples of an apparatus for forming the inorganic seal film include apparatuses of plasma CVD, sputtering, and ion plating. However, the materials and the apparatuses are not limited thereto.

The organic EL element structured as described above emits light with the electroluminescence phenomenon produced when holes and electrons are injected into the organic EL layer 4 through the first electrode 3 and the second electrode 5 and the holes and electrons are recombined within the organic light-emitting layer. As schematically shown in FIG. 2(a), however, if the distance between the electrodes 3 and 5 is reduced in some part due to flaws of the anode or a foreign matter 8 such as minute dust, an electric current is concentrated there because of a nonuniform electric field or the like to generate heat which then causes phenomena such as melting, vaporization, sublimation of the organic EL layer 4, and the melting of the second electrode 5, successively. On the other hand, as schematically shown in FIG. 2(b), on the upper surface side of the second electrode 5, the portion of the low-temperature sublimation layer 6 adjacent to the spot where the heat is generated locally sublimes and expands before the second electrode 5 is melted, and the expanded gas pushes the inorganic seal film 7 upward to form a void (open space) 61. When the heat is generated continuously and the melting point of the second electrode 5 is reached, the second electrode 5 extends into the void 61 to be in the opened state. The opened state of the second electrode 5 eliminates the concentration of the electric current to lower the temperature of the second electrode in which the heat was locally generated. This changes the gas, which expanded to push up the inorganic seal film 7, into the original solid. The area where the electrode is in the opened state is a non-light-emitting area, but the non-light-emitting area has a negligible size and the remaining area can achieve light-emitting operation normally as described above. While the electrode can be in the opened state with the abovementioned process in a normal lighting state in the organic EL element of Embodiment 1, the electrode may be in the opened state by applying a reverse bias voltage.

According to Embodiment 1 described above, the low-temperature sublimation layer 6 made of the material subliming at the temperature lower than the melting point of the second electrode 5 is formed between the second electrode 5 and the inorganic seal film 7. Even when an electric current is locally concentrated, the layer 6 sublimes to form the void 61 before the second electrode 5 is melted, so that the second electrode 5 extends into the void 61 to be in the opened state. This can prevent occurrence of a secondary fault of an electrical short circuit to maintain the normal operation of the element. In addition, since the void 61 is formed between the second electrode 5 and the inorganic seal film 7 to allow the electrode to be in the opened state, any defect in the inorganic seal film 7 can be avoided, and the inorganic seal film 7 can prevent entry of water vapor and oxygen thereafter. The layer is formed such that it is usually solid but sublimes into gas only when the local concentration of an electric current occurs, so that the strength of the element is not reduced and the manufacture of the element (deposition) can be performed easily.

When the low-temperature sublimation layer 6 is made of the same material as that of the organic EL layer 4 such as CuPc, the low-temperature sublimation layer 6 and the organic EL layer 4 can be sublimed at the approximately same time, and the expansion pressure of the gas after the sublimation on the upper surface side of the second electrode 5 can balance the expansion pressure on the lower surface side. This can prevent the expansion pressure on the upper surface side from exceeding that on the lower surface side and from pushing the second electrode 5 downward.

If the low-temperature sublimation layer 6 is formed by using the material which sublimes at the temperature lower than the sublimation temperature of the material of the layer that has the highest sublimation temperature in the organic EL layer 4 having the multi-layered structure, the layer having the highest sublimation temperature in the organic EL layer 4 changes into gas after the low-temperature sublimation layer 6 sublimes into gas, so that the second electrode 5 can be pushed up more reliably to be in the opened state.

Next, a method of manufacturing the organic EL element structured as shown in FIG. 1 will be described. The description will be given by taking an example in which the first electrode 3 is formed as the anode and the second electrode 5 is formed as the cathode.

First, the anode is formed as the first electrode 3 on the substrate 2. By way of example, a conductive thin film of an anode material is deposited on the surface of the substrate 2 through evaporation or sputtering. If the anode has a stacked structure, conductive thin films are successively deposited. Then, a mask is formed on an upper surface of the deposited conductive thin film with a method such as photolithography, and the conductive thin film is patterned with a method such as chemical etching, thereby forming the anode in a predetermined shape.

Next, the substrate 2 having the anode formed thereon is carried into a chamber of an evaporation apparatus (preferably a vacuum evaporation apparatus) to form the organic EL layer 4 on the anode through evaporation. As described above, the organic EL layer 4 is preferably formed of a plurality of thin films including the hole injection layer, the hole transport layer, the light-emitting layer, and the electron injection layer. In this case, the organic EL layer 4 is preferably formed by using the same chamber or multiple chambers to evaporate the layers successively without exposing them to the atmosphere.

After the organic EL layer 4 is formed as described above, the cathode serving as the second electrode 5 is deposited through evaporation by using the same chamber or multiple chambers without exposure to the atmosphere, and the low-temperature sublimation layer 6 is deposited on an upper surface of the cathode through evaporation. In the evaporation, the materials of the films can be heated with resistance heating, induction heating, dielectric heating, electric beam heating, laser heating or the like.

Next, the substrate 2 having the low-temperature sublimation layer 6 formed thereover is carried into a chamber of a plasma CVD apparatus to form the inorganic seal film 7 without exposure to the atmosphere. By way of example, for forming a thin film made of silicon nitride as the inorganic seal film 7, silane gas (SiH₄) and nitrogen gas (N₂) are used as material gas to perform deposition with a plasma CVD method.

The manufacturing trough the process described above can provide the organic EL element with no water vapor or the like attached to the surface or the interface of the organic EL layer 4, the cathode, or the low-temperature sublimation layer 6. However, the manufacturing method is not limited to the abovementioned one, and it is possible to perform the deposition by using a coating application method such as a spin coating method and a dipping method, a printing method such as a screen printing method and an inkjet method, and a laser transfer method as appropriate.

### Embodiment 2

Next, an organic EL element according to Embodiment 2 of the present invention will be described with reference to FIGS. 3(a) and 3(b). Components identical to those in Embodiment 1 described above are designated with the same reference numerals and detailed description thereof is omitted.

As schematically shown in FIG. 3(a), the organic EL element of Embodiment 2 is formed in the same manner as the organic EL element shown in FIG. 1 except for a buffer layer serving as a buffering layer 9 formed inside an inorganic seal film 7. Specifically, the organic EL element of Embodiment 2 includes the buffering layer 9 between a low-temperature sublimation layer 6 and the inorganic seal film 7 placed thereover.

The buffering layer 9 may be formed of a material softer than that of the inorganic seal film 7, and an electrical insulating polymer compound is preferably used. As an example, it is possible to use polyparaxylylene, polyethylene, polytetrafluoroethylene, polyvinyltrimethylsilane, polymethyltrimethoxysilane, and polysiloxane which may be deposited with a CVD method. Preferably, polyparaxylylene is used. In Embodiment 2, the buffering layer 9 is deposited to have a thickness of 500 nm to 10000 nm, for example.

The organic EL layer of the abovementioned structure can be manufactured similarly to Embodiment 1 until the deposition of the low-temperature sublimation layer 6. In Embodiment 2, after the low-temperature sublimation layer 6 is formed, the element being manufactured is carried into a chamber of a CVD apparatus, which is one of vacuum evaporation apparatuses, without exposure to the atmosphere, and the buffering layer 9 is deposited with the CVD method. Then, the element is carried into a chamber of a plasma CVD apparatus without exposure to the atmosphere to deposit the inorganic seal film 7.

In the organic EL element of Embodiment 2, as in the organic EL element of Embodiment 1, even when a leakage current causes concentration of an electric current, the low-temperature sublimation layer 6 sublimes and the resulting expanded gas pushes the inorganic seal film 7 upward to form a void 61. This allows an electrode to be in an opened state to prevent an electrical short circuit. In addition, according to Embodiment 2, as schematically shown in FIG. 3(b), the buffering layer 9 is formed between the low-temperature sublimation layer 6 and inorganic seal film 7 placed thereover, so that the buffering layer 9 can absorb the stress of the expanded gas. This enables more reliable prevention of occurrence of any defect such as a crack and peeling in the inorganic seal film 7.

The deposition with the CVD method results in the buffering layer 9 which covers not only an upper surface of the low-temperature sublimation layer 6 but also a side over the organic EL layer 4. This can enhance the effect of preventing entry of water vapor and oxygen.

The method of depositing the buffering layer 9 is not limited to the abovementioned CVD method. The deposition may be performed with a PVD method by using a material such as polyethylene, polypropylene, polysthylene, polymethylmethacrylate, polyimide, polyurea, a fluorine-based polymer compound, polytetrafluoroethylene, polychloro-trifluoroethylene, polydichlorodifluoroethylene, a copolymer of chlorotrifluoroethylene and dichlorodifluoroethylene, and a fluorine-containing copolymer having a cyclic structure.

### Embodiment 3

Next, an organic EL element according to Embodiment 3 of the present invention will be described. The organic EL element of Embodiment 3 is formed in the same manner as the organic EL element of Embodiment 1 or 2 except that a low-temperature sublimation layer 6 is made of a material which decomposes at a temperature lower than that of a second electrode 5. Examples of the material of the low-temperature sublimation layer 6 that decomposes at a temperature lower than that of the second electrode 5 include tris(8-hydroxyquinolinate) aluminum (Alq₃) (decomposition temperature: approximately 420° C.).

In the organic EL element of Embodiment 3, as in the organic EL element of Embodiment 1, even when a leakage current causes concentration of an electric current, the low-temperature sublimation layer 6 sublimes and the resulting expanded gas pushes the inorganic seal film 7 upward to form a void 61. This allows an electrode to be in an opened state to prevent an electrical short circuit. In addition, according to Embodiment 3, even when the leakage current is eliminated to lower the temperature, the gas after the sublimation does not return to solid but maintains the gaseous form, so that the void 61 is present thereafter with its volume unchanged. This provides the advantage that the second electrode 5 is less likely to approach a first anode 3. Specifically, Alq₃ used as the material decomposes into H₂, CO₂ or the like present in gaseous form at ordinary temperature, so that the volume of the void 61 is hardly changed. In addition, since the low-temperature sublimation layer 6 is formed by using the material having the sublimation temperature (sublimation temperature of Alq₃: approximately 310° C.) lower than that of the material having the highest sublimation temperature (for example, sublimation temperature of CuPc: approximately 460° C.) in the multi-layered film constituting the organic EL layer 4, the layer having the highest sublimation temperature in the organic EL layer 4 is changed into gas after the low-temperature sublimation layer 6 sublimes into gas. Thus, the second electrode 3 can be pushed up more reliably to be in the opened state.

### Embodiment 4

Next, an organic EL element according to Embodiment 4 of the present invention will be described with reference to FIG. 4. Components identical to those in Embodiment 1 described above are designated with the same reference numerals and detailed description thereof is omitted.

The organic EL element of Embodiment 4 is formed in the same manner as the organic EL element 1 in FIG. 1 except that a second electrode is formed by stacking conductive thin films having different melting points in the order of decreasing melting point from an organic EL layer 4 toward an inorganic seal film 7. The conductive thin films can be made of the same materials as those in Embodiment 1 described above.

When the second electrode 5 is set as a cathode, a two-layer structure is preferably used by stacking a first conductive thin film 5a made of aluminum and a second conductive thin film 5b having a melting point lower than that of aluminum. In this case, the ratio of the thickness of the second conductive thin film 5b having the lower melting point is preferably higher than that of the first conductive thin film 5a made of aluminum. For example, any of indium (In), tin (Sn), and zinc (Zn) can be used for the material of the second conductive thin film 5b, but the material is not limited thereto.

In the organic EL element of Embodiment 4, as in the organic EL element of Embodiment 1, even when a leakage current causes concentration of an electric current, a low-temperature sublimation layer 6 sublimes and the resulting expanded gas pushes the inorganic seal film 7 upward to form a void 61. This allows the second electrode 5 to be in an opened state to prevent an electrical short circuit. In addition, according to Embodiment 4, the second electrode 5 has the multi-layered structure in which the first conductive thin film 5a made of aluminum used for the first layer favorably maintains the characteristics which should be provided by the organic EL element and the second electrode is melted in a lower heat state, thereby allowing a reduction in volume of the void 61 formed through the sublimation of the low-temperature sublimation layer 6, by way of example. In other words, the opened state can be made at the lower temperature to prevent extreme progress of the sublimation. In this case, the film thickness of aluminum is preferably equal to or smaller than 10 nm so that the aluminum film is allowed to be in the opened state in response to a slight pressure when the ambient temperature becomes lower than the melting point of aluminum and higher than the melting point of the second conductive thin film. As a result, it is possible to prevent occurrence of any defect such as a crack and peeling in the inorganic seal film 7 more reliably. The buffering layer 9 used in Embodiment 2 may also be added to the structure of Embodiment 4, and the materials described in Embodiment 3 may be used for the materials of the low-temperature sublimation layer 6.

As described above, the present invention has the structure including the inorganic seal film formed in intimate contact in order to reduce the thickness of the element, for example. The first electrode, the organic EL layer, the second electrode, the low-temperature sublimation layer made of the material subliming at the temperature lower than the melting point of the second electrode, and the inorganic seal film are stacked in order over the substrate. Even when a leakage current occurs, the low-temperature sublimation layer sublimes to form the void into which the second electrode extends to be in the opened state. It is thus possible to prevent an electrical short circuit.

### EXAMPLES

While Examples of the present invention will be described, the present invention is not limited by the following Examples.

### Example 1

A first electrode 3 made of light-transmitting ITO was deposited on a transparent glass substrate 2. Over the electrode 3, a hole injection layer made of CuPc (copper phthalocyanine) of 25 nm, a hole transport layer made of α-NPD (diphehylamine derivative) of 40 nm, a light-emitting layer made of Alq₃ (aluminum chelate complex) of 60 nm, and an electron injection layer made of Li₂O (lithium oxide) of 0.5 nm were deposited in order with evaporation to form an organic EL layer 4. Then, a second electrode 5 made of Al of 100 nm (melting point: 660.1° C.) was deposited thereon with evaporation. Next, CuPc (sublimation temperature: approximately 460° C.) was deposited on the second electrode 5 to have a thickness of 300 nm to form a low-temperature sublimation layer 6. The multi-layered structure on the glass substrate 1 thus provided was carried and placed into a chamber of plasma CVD without exposure to the atmosphere, and an inorganic seal film 7 of 1000 nm made of SiNₓ (silicon nitride) was deposited on the surface thereof to produce an organic EL element.

### Example 2

In Example 2, an organic EL element was produced in the same manner as in Example 1 except for a buffering layer 9 formed on an inner surface of an inorganic seal film 7. Specifically, Example 2 was the same as Example 1 until the deposition of a low-temperature sublimation layer 6, but then, the multi-layered structure on a glass substrate 2 thus provided was carried and placed into a chamber of a CVD apparatus without exposure to the atmosphere, and a polyparaxylylene film of 1000 nm was deposited to form the buffering layer 9. Next, the device having the buffering layer 9 formed therein was carried and placed into a chamber of a plasma CVD apparatus without exposure to the atmosphere, and the inorganic seal film 7 of 1000 nm made of SiNₓ (silicon nitride) was deposited to produce the organic EL element.

### Example 3

In Example 3, an organic EL element was produced in the same manner as in Example 1 except that a low-temperature sublimation layer 6 of 300 nm was deposited by using tris(8-hydroxyquinolinate) aluminum (Alq₃) as a material (sublimation temperature: approximately 310° C., decomposition temperature: approximately 420° C.).

### Example 4

In Example 4, an organic EL element was produced in the same manner as in Example 3 except that a second electrode including two layers was deposited. The second electrode was formed by depositing Al of 5 nm as a first layer and subsequently depositing Zn (melting point: 419.5° C.) of 995 nm having a melting point lower than that of Al.

1-17. (canceled)

18. An organic EL element in which a first electrode, an organic EL layer, a second electrode, and an inorganic seal film are stacked in order over a substrate, comprising:
a low-temperature sublimation layer formed of a material which sublimes at a temperature lower than a melting point of the second electrode on the second electrode, when a leakage current generates heat locally in the second electrode, an adjacent portion of the low-temperature sublimation layer subliming to form a void into which the second electrode extends upward; and
a buffering layer formed of an electrical insulating polymer compound between the low-temperature sublimation layer and the inorganic seal film.

19. The organic EL element according to claim 18, wherein the low-temperature sublimation layer has a thickness ranging from 100 nm to 10000 nm.

20. The organic EL element according to claim 18, wherein the low-temperature sublimation layer is formed of a material which decomposes at a temperature lower than the melting point of the second electrode.

21. The organic EL element according to claim 18, wherein the low-temperature sublimation layer is formed of a material which sublimes at a temperature lower than the highest vaporization temperature of a material out of materials forming the organic EL layer.

22. The organic EL element according to claim 18, wherein the low-temperature sublimation layer is formed of one of materials forming the organic EL layer.

23. The organic EL element according to claim 18, wherein the electrical insulating polymer compound forming the buffering layer is any of polymers including polyparaxylylene, polyethylene, polytetrafluoroethylene, polyvinyltrimethylsilane, polymethyltrimethoxysilane, and polysiloxane.

24. The organic EL element according to claim 18, wherein the second electrode is formed by stacking conductive thin films having different melting points in the order of decreasing melting point from the organic EL layer toward the inorganic seal film.

25. The organic EL element according to claim 24, wherein the second electrode has a two-layer structure including a first conductive thin film made of aluminum placed closer to the organic EL layer and a second conductive thin film placed on the first conductive thin film and having a melting point lower than that of aluminum (Al).

26. The organic EL element according to claim 25, wherein the second conductive thin film having the melting point lower than that of aluminum is formed of metal which is any of indium (In), tin (Sn), and zinc (zn).

27. The organic EL element according to claim 25, wherein the aluminum has a thickness of 10 nm or smaller.

28. A method of manufacturing an organic EL element in which a first electrode, an organic EL layer, a second electrode, and an inorganic seal film are stacked in order over a substrate, comprising:
carrying the substrate having the first electrode formed thereon into an evaporation apparatus to form in order the organic EL layer, the second electrode, and the low-temperature sublimation layer made of a material which sublimes at a temperature lower than a melting point of the second electrode, when a leakage current generates heat locally in the second electrode, an adjacent portion of the low-temperature sublimation layer subliming to form a void into which the second electrode extends upward; and
carrying the substrate having the low-temperature sublimation layer formed thereover into a buffering-film deposition apparatus without exposure to the atmosphere to form a buffering layer formed of an electrical insulating polymer compound on the low-temperature sublimation layer; and
carrying the substrate having the buffering layer formed thereover into an inorganic-seal-film deposition apparatus without exposure to the atmosphere to form the inorganic seal film.

29. The method of manufacturing an organic EL element according to claim 28, wherein the low-temperature sublimation layer is formed of a material which decomposes at a temperature lower than the melting point of the second electrode.

30. The method of manufacturing an organic EL element according to claim 28, wherein the electrical insulating polymer compound forming the buffering layer is any of polymers including polyparaxylylene, polyethylene, polytetrafluoroethylene, polyvinyltrimethylsilane, polymethyltrimethoxysilane, and polysiloxane.

31. The method of manufacturing an organic EL element according to claim 28, wherein the second electrode is formed by stacking a plurality of conductive thin films in the order of decreasing melting point from the organic EL layer toward the inorganic seal film.

32. The method of manufacturing an organic EL element according to 31, wherein the second electrode is formed by forming a first conductive thin film made of aluminum on an upper surface of the organic EL layer and placing a second conductive thin film having a melting point lower than that of aluminum on the first conductive thin film.

33. The method of manufacturing an organic EL element according to claim 32, wherein the second conductive thin film having the melting point lower than that of aluminum is made of metal which is any of indium (In), tin (Sn), and zinc (zn).
